(19) United States
(12) Patent Application Publication
(10) Pub. No.: US 2015/0187869 A1
(43) Pub. Date: Jul. 2, 2015

(54) POWER SEMICONDUCTOR DEVICE

(71) Applicant: SAMSUNG ELECTRO-MECHANICS CO., LTD., Suwon-Si (KR)

(72) Inventors: Jae Hoon PARK, Suwon-Si (KR); Kyu Hyun Mo, Suwon-Si (KR); Jae Kyu Sung, Suwon-si (KR); Kee Ju Um, Suwon-Si (KR); In Hyuk Song, Suwon-Si (KR)

(73) Assignee: SAMSUNG ELECTRO-MECHANICS CO., LTD., Suwon-Si (KR)

(21) Appl. No.: 14/272,009

(22) Filed: May 7, 2014

(30) Foreign Application Priority Data
Dec. 27, 2013 (KR) 10-2013-0165331

(51) Int. Cl. H01L 29/06; H01L 29/10; H01L 29/739

(52) U.S. Cl. CPC H01L 29/063; H01L 29/7397; H01L 29/1095

(57) ABSTRACT

A power semiconductor device may include: a first conductivity-type first semiconductor region; a resurf region disposed in the first semiconductor region and including first conductivity-type second semiconductor regions and second conductivity-type third semiconductor regions alternately disposed in a width direction; a first conductivity-type first cover region disposed in the first semiconductor region, disposed to be contiguous with an upper surface of the resurf region, and having an impurity concentration higher than that of the first semiconductor region; a second conductivity-type fourth semiconductor region disposed above the first semiconductor region; a first conductivity-type fifth semiconductor region disposed on an inner side of an upper portion of the fourth semiconductor region; and a trench gate disposed to penetrate from the fifth semiconductor region to a portion of an upper portion of the first semiconductor region and including a gate insulating layer and a conductive material.

### CROSS-REFERENCE TO RELATED APPLICATION

This application claims the benefit of Korean Patent Application No. 10-2013-0165331 filed on Dec. 27, 2013, with the Korean Intellectual Property Office, the disclosure of which is incorporated herein by reference.

### BACKGROUND

The present disclosure relates to a power semiconductor device having an enhanced blocking voltage.

An insulated-gate bipolar transistor (IGBT) is a transistor with a gate manufactured by using a metal-oxide semiconductor (MOS) structure and forming a p-type collector layer on a rear surface thereof having bipolarity.

Since the development of conventional power Metal-Oxide Semiconductor Field Emission Transistors (MOSFET), such MOSFETs have been used in fields in which fast switching characteristics are required.

However, due to inherent structural limitations of MOSFETs, bipolar transistors, thyristors, gate turn-off thyristors (GTO), and the like, have been used in fields in which high voltage are required.

IGBTs, featuring low forward loss and fast switching speeds, tend to extendedly applied to applications in various fields for which existing thyristors, bipolar transistors, MOSFETs, and the like are unsuitable.

As for an operating principle of an IGBT, in the case that an IGBT device is turned on and a voltage higher than that of a cathode is applied to an anode, while a voltage higher than a threshold value of the device is applied to a gate electrode, a polarity of a surface of a p-type body region positioned in a lower end portion of the gate electrode is reversed to form an n-type channel.

An electron current injected into a drift region through the n-type channel induces injection of a hole current from a p-type collector layer having a high concentration positioned in a lower portion of the IGBT device, such as a base current of a bipolar transistor.

The injection of the minority carrier having a high concentration increases conductivity in the drift region by tens to hundreds of times (an order of magnitude of one or two), causing conductivity modulation.

Unlike a MOSFET, a resistance component in the drift region may be reduced in size to be significantly low due to the conductivity modulation, and thus, extremely high voltages may be applied to IGBT devices.

A current flowing to a cathode may be divided into an electron current, flowing through a channel, and a hole current, flowing through a junction between a p-type body and an n-type drift region.

An IGBT may have a PNP structure between an anode and a cathode in terms of a substrate structure, so unlike a MOSFET, a diode may not be installed, and thus, a separate diode may need to be connected to an IGBT through an inverse-parallel connection.

Major characteristics of IGBTs include maintaining a blocking voltage, reducing conduction loss, and increasing a switching speed.

Namely, according to a conventional technology trend of IGBT devices, IGBT devices are reduced in thickness as much as possible by a method such as grinding a portion of a rear surface thereof in order to reduce an ON voltage and OFF loss.

However, a reduction in the thickness of IGBT devices tends to lead to a reduction in the heat capacity thereof, resulting in a reduction in short circuit tolerable properties (or short circuit capability).

Thus, a technique of simultaneously enhancing all of an ON voltage, OFF loss, and short circuit capability of IGBT devices, while maintaining thicknesses thereof, is required.

### SUMMARY

An aspect of the present disclosure may provide a power semiconductor device capable of simultaneously enhancing all of an ON voltage, OFF loss, and short circuit capability of an IGBT device, while maintaining a thickness thereof.

According to an aspect of the present disclosure, a power semiconductor device may include: a first conductivity-type first semiconductor region; a resurf region disposed in the first semiconductor region and including first conductivity-type second semiconductor regions and second conductivity-type third semiconductor regions alternately disposed in a width direction; a first conductivity-type first cover region disposed in the first semiconductor region, disposed to be contiguous with an upper surface of the resurf region, and having an impurity concentration higher than that of the first semiconductor region; a second conductivity-type fourth semiconductor region disposed above the first semiconductor region; a first conductivity-type fifth semiconductor region disposed on an inner side of an upper portion of the fourth semiconductor region; and a trench gate disposed to penetrate from the fifth semiconductor region to a portion of an upper portion of the first semiconductor region and including a gate insulating layer disposed on a surface thereof and a conductive material filling the interior of the trench.

When a width of each of the second semiconductor regions is W₂, an impurity concentration in each of the second semiconductor regions is C₂, a width of each of the third semiconductor regions is W₃, and an impurity concentration in each of the third semiconductor regions is C₃, W₂×C₂=W₃×C₃ may be satisfied.

When a width of each of the second semiconductor regions is W₂, an impurity concentration in each of the second semiconductor regions is C₂, a width of each of the third semiconductor regions is W₃, an impurity concentration in each of the third semiconductor regions is C₃, a thickness of the first cover region is T_{c1}, and an impurity concentration in the first cover region is C_{c1}, T_{c1}×C_{c1}≧W₂×C₂ may be satisfied.

The power semiconductor device may further include: a second cover region having a first conductivity-type second cover region disposed in the first semiconductor region, disposed to be contiguous with a lower surface of the resurf region, and having an impurity concentration higher than that of the first semiconductor region.

When a width of each of the second semiconductor regions is W₂, an impurity concentration in each of the second semiconductor regions is C₂, a width of each of the third semiconductor regions is W₃, and an impurity concentration in each of the third semiconductor regions is C₃, a thickness of the second cover region is T_{c2}, and an impurity concentration in the second cover region is C_{c2}, T_{c2}×C_{c2}≧W₂×C₂ may be satisfied.

According to another aspect of the present disclosure, a power semiconductor device may include: a first conductivity-type first semiconductor region; a first conductivity-type second cover region disposed in the first semiconductor region and having an impurity concentration higher than that of the first semiconductor region; a resurf region disposed in the first semiconductor region, disposed to be contiguous with an upper surface of the second cover region, and including first conductivity-type second semiconductor regions and second conductivity-type third semiconductor regions alternately disposed in a width direction; a second conductivity-type fourth semiconductor region disposed above the first semiconductor region; a first conductivity-type fifth semiconductor region disposed on an inner side of an upper portion of the fourth semiconductor region; and a trench gate disposed to penetrate from the fifth semiconductor region to a portion of an upper portion of the first semiconductor region and including a gate insulating layer disposed on a surface thereof and a conductive material filling the interior of the trench.

According to another aspect of the present disclosure, a power semiconductor device may include: a first conductivity-type first semiconductor region; a resurf region disposed in the first semiconductor region and including first conductivity-type second semiconductor regions and second conductivity-type third semiconductor regions alternately disposed in a width direction; a first conductivity-type first cover region disposed in the first semiconductor region, disposed to be contiguous with an upper surface of the resurf region, and having an impurity concentration higher than that of the first semiconductor region; a second conductivity-type fourth semiconductor region disposed above the first semiconductor region; a first conductivity-type fifth semiconductor region disposed on an inner side of an upper portion of the fourth semiconductor region; and a gate disposed above the fourth semiconductor region.

When a width of each of the second semiconductor regions is W₂, an impurity concentration in each of the second semiconductor regions is C₂, a width of each of the third semiconductor regions is W₃, and an impurity concentration in each of the third semiconductor regions is C₃, W₂×C₂=W₃×C₃ may be satisfied.

When a width of each of the second semiconductor regions is W₂, an impurity concentration in each of the second semiconductor regions is C₂, a width of each of the third semiconductor regions is W₃, an impurity concentration in each of the third semiconductor regions is C₃, a thickness of the first cover region is T_{c1}, and an impurity concentration in the first cover region is C_{c1}, T_{c1}×C_{c1}≧W₂×C₂ may be satisfied.

The power semiconductor device may further include: a second cover region having a first conductivity-type second cover region disposed in the first semiconductor region, disposed to be contiguous with a lower surface of the resurf region, and having an impurity concentration higher than that of the first semiconductor region.

When a width of each of the second semiconductor regions is W₂, an impurity concentration in each of the second semiconductor regions is C₂, a width of each of the third semiconductor regions is W₃, and an impurity concentration in each of the third semiconductor regions is C₃, a thickness of the second cover region is T_{c2}, and an impurity concentration in the second cover region is C_{c2}, T_{c2}×C_{c2}≧W₂×C₂ may be satisfied.

According to another aspect of the present disclosure, a power semiconductor device may include: a first conductivity-type first semiconductor region; a first conductivity-type second cover region disposed in the first semiconductor region and having an impurity concentration higher than that of the first semiconductor region; a resurf region disposed in the first semiconductor region, disposed to be contiguous with an upper surface of the second cover region, and including first conductivity-type second semiconductor regions and second conductivity-type third semiconductor regions alternately disposed in a width direction; a second conductivity-type fourth semiconductor region disposed above the first semiconductor region; a first conductivity-type fifth semiconductor region disposed on an inner side of an upper portion of the fourth semiconductor region; and a gate disposed above the fourth semiconductor region.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view schematically illustrating a power semiconductor device in which a first cover region is formed above a resurf region according to an exemplary embodiment of the present disclosure;

FIG. 2 is a cross-sectional view schematically illustrating a power semiconductor device in which first and second cover regions are respectively formed above and below a resurf region according to an exemplary embodiment of the present disclosure;

FIG. 3 is a cross-sectional view schematically illustrating a power semiconductor device in which a second cover region is formed below a resurf region according to an exemplary embodiment of the present disclosure;

FIG. 4 is a cross-sectional view schematically illustrating a power semiconductor device in which a first cover region is formed above a resurf region according to another exemplary embodiment of the present disclosure;

FIG. 5 is a cross-sectional view schematically illustrating a power semiconductor device in which first and second cover regions are respectively formed above and below a resurf region according to another exemplary embodiment of the present disclosure; and

FIG. 6 is a cross-sectional view schematically illustrating a power semiconductor device in which a second cover region is formed below a resurf region according to another exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

A power switch may be implemented by any one of a power metal-oxide semiconductor field emission transistor (MOSFET), an insulated-gate bipolar transistor (IGBT), various types of thyristor, or the like. Most new techniques disclosed herein will be described based on IGBTs. However, various exemplary embodiments disclosed herein are not limited to IGBTs and may be applied to any type of power switch technique, including power MOSFETs and various types of thyristors, besides IGBTs. In addition, various exemplary embodiments of the present disclosure are described to include particular p-type and n-type regions. However, obviously, the exemplary embodiments described herein may also be applied to devices including regions having opposite conductivity types in the same manner.

Also, as used herein, p-type and n-type may be defined as a first conductivity-type or a second conductivity-type. Meanwhile, first and second conductivity-types refer to different conductivity-types.

Also, in general, positive (+) refers to an element doped at a high concentration and negative (−) refers to an element state doped at a low concentration.

Hereinafter, for clarification, a first conductivity-type will be referred to as an n-type, while a second conductivity-type will be referred to as a p-type, but the present disclosure is not limited thereto.

Also, a first semiconductor region will be referred to as a drift region, a fourth semiconductor region will be referred to as a body region, and a fifth semiconductor region will be referred to as an emitter region, but the present disclosure is not limited thereto.

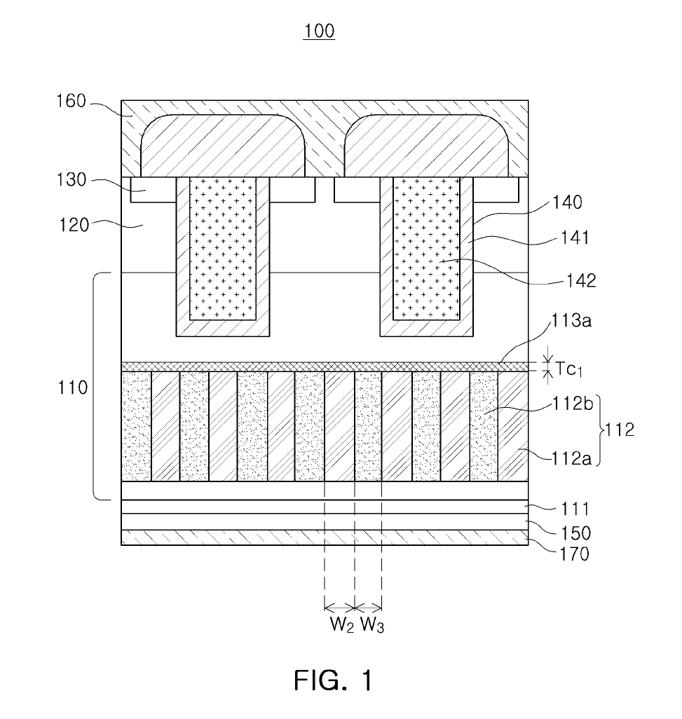

FIG. 1 is a cross-sectional view schematically illustrating a power semiconductor device 100 in which a first cover region 113a is formed above a resurf region 112 according to an exemplary embodiment of the present disclosure.

A structure of the power semiconductor device 100 according to an exemplary embodiment of the present disclosure will be described with reference to FIG. 1. The power semiconductor device 100 according to an exemplary embodiment of the present disclosure may include a drift region 110 including a resurf region 112, a body region 120, an emitter region 130, and a trench gate 140 penetrating from the emitter region 130 to the drift region 110.

The drift region 110 may be formed by injecting an n-type impurity having a low concentration.

Thus, in order to maintain a blocking voltage of the device, the drift region 110 is relatively thick.

The drift region 110 may include a buffer region 111 formed on a lower surface thereof.

The buffer region 111 may be formed by injecting an n-type impurity into a rear surface of the drift region 110.

The buffer region 111 may serve to hinder expansion of a depletion region of the device, helping to maintain a blocking voltage of the device.

Thus, when the buffer region 111 is formed, the drift region 110 may be formed to be thinner, reducing the size of the power semiconductor device.

A p-type impurity may be injected into an upper portion of the drift region 110 to form the body region 120.

The body region 120 may have p-type conductivity, forming a p-n junction with the drift region 110.

An n-type impurity having a high concentration may be injected into the interior of the upper surface of the body region 120 to form the emitter region 130.

The trench gate 140 may be formed to penetrate from the emitter region 130, through the body region 120, to a portion of the drift region 110.

Namely, the trench gate 140 may be formed to penetrate from the emitter region 130 into a portion of the drift region 110.

The trench gate 140 may be formed extendedly in one direction and may be arranged at a predetermined interval in a direction perpendicular to the one direction.

A gate insulating layer 141 may be formed in portions of the trench gate 140 in contact with the drift region 110, the body region 120, and the emitter region 130.

The gate insulating layer 141 may be formed of silicon oxide (SiO₂), but the present disclosure is not limited thereto.

The interior of the trench gate 140 may be filled with a conductive material 142.

The conductive material 142 may be polysilicon (Poly-Si) or a metal, but the present disclosure is not limited thereto.

The conductive material 142 is electrically connected to a gate electrode (not shown) to control an operation of the power semiconductor device 100 according to the exemplary embodiment of the present disclosure.

In the case that a positive (+) voltage is applied to the conductive material 142, a channel is formed in the body region 120.

In detail, in the case that a positive (+) voltage is applied to the conductive material 142, electrons present in the body region 120 are attracted toward the trench gate 140, so electrons gathering at the trench gate 140 form a channel.

Namely, the trench gate 140 attracts electrons to form a channel in a depletion region with no carriers, due to electron-hole recombination occurring at a p-n junction, allowing a current to flow.

A p-type impurity may be injected into a lower surface of the drift region 110 or into a lower surface of the buffer region 111 to form a collector region 150.

In a case in which the power semiconductor device is an insulated-gate bipolar transistor (IGBT), the collector region 150 may provide holes to the power semiconductor device 100.

The injection of holes, minority carriers, having a high concentration, causes conductivity modulation in which conductivity is increased by tens to hundreds of times in the drift region 110.

In a case in which the power semiconductor device is a metal-oxide semiconductor field emission transistor (MOSFET), the collector region 150 may have n-type conductivity.

An emitter metal layer 160 may be formed on the emitter region 130 and an exposed upper surface of the body region 120, and a collector metal layer 170 may be formed on a lower surface of the collector region 150.

The power semiconductor device 100 according to the present exemplary embodiment may further include a resurf region 112 formed in the drift region 110.

The resurf region 112 may include n-type second semiconductor regions 112a and p-type third semiconductor regions 112b alternately formed in a width direction.

An impurity concentration in each of the second semiconductor regions 112a may be higher than that of the drift region 110.

The second semiconductor regions 112a may provide a path allowing a current to easily flow in the drift region 110.

Namely, since the second semiconductor regions 112a have an impurity concentration higher than that of the drift region 110, when the second semiconductor regions 112a are formed, resistance of a path, along which a current flows, may be reduced, and thus, loss when the power semiconductor device 100 is conducted may be reduced.

Thus, ON voltage performance of the power semiconductor device 100 according to the present exemplary embodiment may be enhanced.

In the case that the power semiconductor device 100 transitions from a conducted state to an OFF state, electrons and holes, which have not been rapidly removed, may remain in the drift region 110.

The residual electrons and holes may reduce switching performance of the power semiconductor device 100 and further increase OFF loss in the power semiconductor device 100.

The residual electrons are moved toward a collector so as to be removed, and the residual holes are moved toward an emitter so as to be removed.

Thus, in the event of an OFF operation, the second semiconductor regions 112a may provide a path allowing electrons to be quickly moved toward the collector, and the third semiconductor regions 112b may provide a path allowing holes to be quickly moved toward the emitter.

Also, the second semiconductor regions 112a and the third semiconductor regions 112b may provide a recombination center with respect to the residual electrons and holes.

Thus, in the case in which the resurf region 112 is formed, it may provide a path allowing electrons and holes to be quickly moved out and a recombination center allowing electrons and holes to be quickly recombined.

Thus, the power semiconductor device 100 according to the present exemplary embodiment may reduce OFF loss.

The first cover region 113a may be formed on the resurf region 112.

In the case that the power semiconductor device 100 operates in a blocking mode, a depletion layer formed in a portion where a p-type semiconductor region and an n-type semiconductor region are in contact expands.

Such a depletion layer increasingly expands as a voltage of the blocking mode is increased.

In case of the resurf region 112, since the n-type second semiconductor regions 112a and the p-type third semiconductor regions 112b are in contact, a depletion layer even in the resurf region 112 also expands.

In the case that a voltage is low in an initial stage of the blocking mode, the depletion layer expands in a width direction in the interfaces between the second semiconductor regions 112a and the third semiconductor regions 112b.

In order to enhance a blocking voltage of the power semiconductor device 100, an extra space is required for the depletion layer to expand.

Thus, when a width of each of the second semiconductor regions 112a is W₂, an impurity concentration in each of the second semiconductor regions 112a is C₂, a width of each of the third semiconductor regions 112b is W₃, and an impurity concentration in each of the third semiconductor regions 112b is C₃, W₂, C₂, W₃, and C₃ may be adjusted to satisfy W₂×C₂=W₃×C₃.

In a case in which an amount of impurities of the second semiconductor regions 112a and that of the third semiconductor regions 112b are equal, the second semiconductor regions 112a and the third semiconductor regions 112b may be depleted at the same time.

If the second semiconductor regions 112a and the third semiconductor regions 112b are not depleted at the same time, a depletion layer may be expanded to upper and lower portions of a first depleted region at a low voltage in a greater amount than in the case in which the second semiconductor regions 112a and the third semiconductor regions 112b are depleted at the same time, reducing a blocking voltage of the power semiconductor device 100.

Thus, in the power semiconductor device 100 according to the present exemplary embodiment, when the width of each of the second semiconductor regions 112a is W₂, the impurity concentration in each of the second semiconductor regions 112a is C₂, the width of each of the third semiconductor regions 112b is W₃, and the impurity concentration in each of the third semiconductor regions 112b is C₃, since W₂×C₂=W₃×C₃ is satisfied, a blocking voltage of the power semiconductor device 100 may be increased.

In the case that the voltage in the blocking mode is increased, the depletion layer depletes the entirety of the resurf region 112 and expands to upper and lower sides.

In the power semiconductor device 100 according to the present exemplary embodiment, an n-type first cover region 113a may be formed on the resurf region 112.

In the case that the power semiconductor device 100 operates in the blocking mode, the first cover region 113a may serve as a field stop, preventing the depletion layer from expanding into the drift region 110 and to upper sides of the drift region 110.

Thus, in the case that the power semiconductor device 100 operates in the blocking mode of a high voltage, the first cover region 113a may serve to protect the p-n junction formed as the drift region 110 and the body region 120 are formed to be in contact.

In order to enhance field stop performance of the first cover region 113a, when the width of each of the second semiconductor regions 112a is W₂, an impurity concentration in each of the second semiconductor regions 112a is C₂, the width of each of the third semiconductor regions 112b is W₃, an impurity concentration in each of the third semiconductor regions 112b is C₃, a thickness of the first cover region 113a is T_{c1}, and an impurity concentration in the first cover region 113a is C_{c1}, T_{c1}×C_{c1}≧W₂×C₂=W₃×C₃ may be satisfied.

The first cover region 113a may not be formed to be in direct contact with the body region 120, and an upper surface of the drift region 110 may be formed to be in direct contact with the body region 120.

Namely, conductivity modulation may be induced by forming an n-type impurity region having a low concentration in an upper portion of the drift region 110.

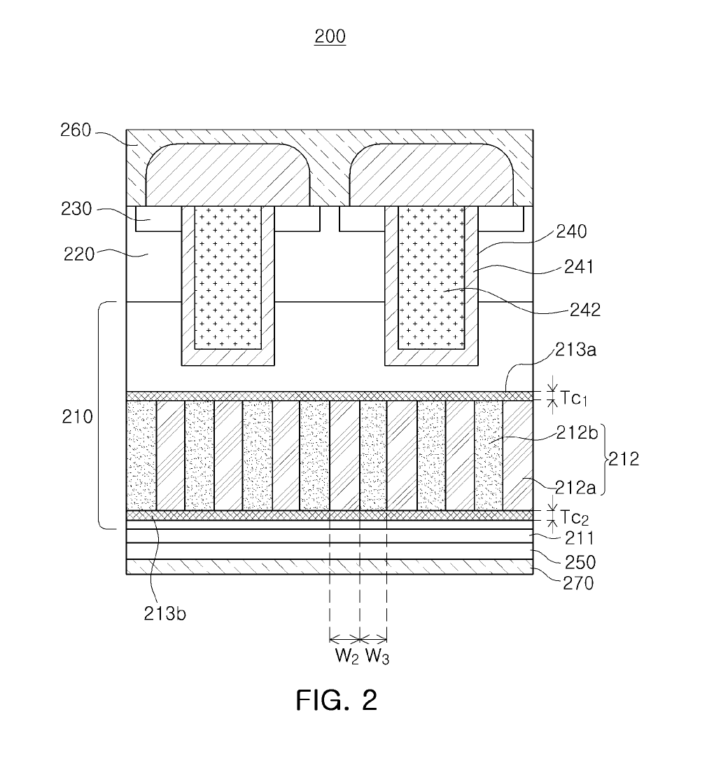

FIG. 2 is a cross-sectional view schematically illustrating a power semiconductor device 200 in which first and second cover regions 213a and 213b are respectively formed above and below a resurf region 212 according to an exemplary embodiment of the present disclosure.

Components not described hereinafter are identical to those of the power semiconductor device 100 illustrated in FIG. 1.

As illustrated in FIG. 2, the first cover region 213a and the second cover region 213b may be formed to be contiguous with upper and lower surfaces of the resurf region 212, respectively.

The second cover region 213b may serve to hinder a depletion layer from expanding downwards in a blocking mode, like the first cover region 213a.

In order to enhance field stop performance of the second cover region 213b, when a width of each of the second semiconductor regions 212a is W₂, an impurity concentration in each of the second semiconductor regions 212a is C₂, a width of each of the third semiconductor regions 212b is W₃, and an impurity concentration in each of the third semiconductor regions 212b is C₃, a thickness of the second cover region 213b is T_{c2}, and an impurity concentration in the second cover region 213b is C_{c2}, T_{c2}×C_{c2}≧W₂×C₂=W₃×C₃ may be satisfied.

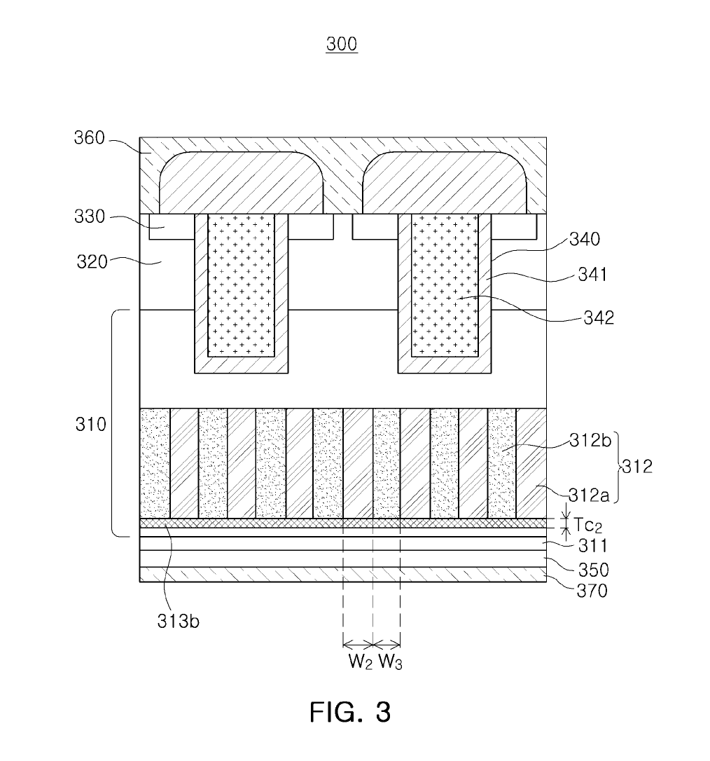

FIG. 3 is a cross-sectional view schematically illustrating a power semiconductor device 300 in which a second cover region 313b is formed below a resurf region 312 according to an exemplary embodiment of the present disclosure.

Components not described hereinafter are identical to those of the power semiconductor device 100 illustrated in FIG. 1.

As illustrated in FIG. 3, the second cover region 313b may be formed only below the resurf region 312.

In a case in which the resurf region 312 is formed below a drift region 310, the second cover region 313b may be formed only below the resurf region 312 to hinder a depletion layer from expanding downwards.

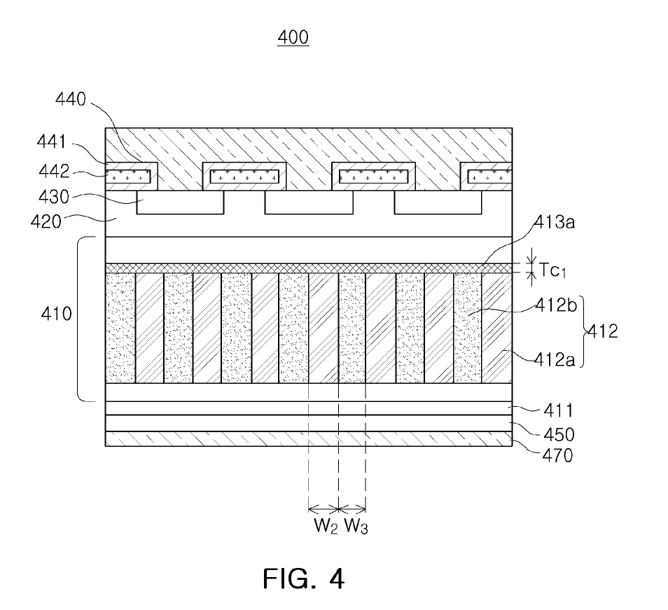

FIG. 4 is a cross-sectional view schematically illustrating a power semiconductor device 400 in which a first cover region 413a is formed above a resurf region 412 according to another exemplary embodiment of the present disclosure.

As for a structure of the power semiconductor device 400 according to another exemplary embodiment of the present disclosure with reference to FIG. 4, the power semiconductor device 400 according to another exemplary embodiment of the present disclosure may include a drift region 410 including a resurf region 412, a body region 420, an emitter region 430, and a trench gate 440 formed above the emitter region 430.

The drift region 410 may be formed by injecting an n-type impurity having a low concentration.

Thus, the drift region 410 may have a relatively large thickness in order to maintain a blocking voltage of the device.

The drift region 410 may include a buffer region 411 formed on a lower surface thereof.

The buffer region 411 may be formed by injecting an n-type impurity into a rear surface of the drift region 410.

The buffer region 411 may hinder a depletion region of the device from expanding, helping maintain a blocking voltage of the device.

Thus, when the buffer region 411 is formed, since the drift region 410 may become thinner, reducing a size of the power semiconductor device 400.

The body region 420 may be formed by injecting a p-type impurity into an upper surface of the drift region 410.

The body region 420 has p-type conductivity, forming p-n junction with the drift region 410.

The emitter region 430 may be formed by injecting n-type impurity having a high concentration into an inner side of the upper surface of the body region 420.

The gates 440 may be formed above the body region 420.

The gates 440 may be formed by forming a gate insulating layer 441 on the body region 420 and stacking a conductive material 442 thereon.

The gate insulating layer 441 may be formed of silicon oxide SiO₂, but the present disclosure is not limited thereto.

The conductive material 442 may be polysilicon (Poly-Si) or a metal, but the present disclosure is not limited thereto.

The conductive material 442 is electrically connected to a gate electrode (not shown) to control an operation of the power semiconductor device 400 according to another exemplary embodiment of the present disclosure.

In the case that a positive (+) voltage is applied to the conductive material 442, a channel is formed in an upper portion of the body region 420.

In detail, in the case that a positive (+) voltage is applied to the conductive material 442, electrons present in the body region 420 are attracted toward the gates 440, so electrons gathering in the body region 440 to form a channel.

Namely, the gates 440 attract electrons to form a channel in a depletion region with no carriers due to electron-hole recombination according to p-n junction, allowing a current to flow.

A p-type impurity may be injected into a lower surface of the drift region 410 or a lower surface of the buffer region 411 to form a collector region 450.

In a case in which the power semiconductor device is an IGBT, the collector region 450 may provide holes to the power semiconductor device 400.

The injection of holes, minority carriers, having a high concentration causes conductivity modulation that conductivity is increased by tens to hundreds of times in the drift region 410.

In a case in which the power semiconductor device is a MOSFET, the collector region 450 may have n-type conductivity.

An emitter metal layer 460 may be formed on the emitter region 430 and an exposed upper surface of the body region 420, and a collector metal layer 470 may be formed on a lower surface of the collector region 450.

The power semiconductor device 400 according to the present exemplary embodiment may further include a resurf region 412 formed in the drift region 410.

The resurf region 412 may include n-type second semiconductor regions 412a and p-type third semiconductor regions 412b alternately formed in a width direction.

An impurity concentration in each of the second semiconductor regions 412a may be higher than that of the drift region 410.

The second semiconductor regions 412a may provide a path allowing a current to easily flow in the drift region 410.

Namely, since the second semiconductor regions 412a have impurity concentration higher than that of the drift region 410, when the second semiconductor regions 412a are formed, resistance of a path, along which a current flows, may be reduced, and thus, loss when the power semiconductor device 400 is conducted may be reduced.

Thus, ON voltage performance of the power semiconductor device 400 according to the present exemplary embodiment may be enhanced.

In the case that the power semiconductor device 400 transitions from a conducted state to an OFF state, electrons and holes, which have not been rapidly removed, may remain in the drift region 410.

The residual electrons and holes may reduce switching performance of the power semiconductor device 400 and further increase an OFF loss in the power semiconductor device 400.

The residual electrons are moved toward a collector so as to be removed, and the residual holes are moved toward an emitter so as to be removed.

Thus, in the event of an OFF operation, the second semiconductor regions 412a may provide a path allowing electrons to be quickly moved toward the collector, and the third semiconductor regions 412b may provide a path allowing holes to be quickly moved toward the emitter.

Also, the second semiconductor regions 412a and the third semiconductor regions 412b may provide a recombination center with respect to the residual electrons and holes.

Thus, in the case in which the resurf region 412 is formed, it may provide a path allowing electrons and holes to be quickly moved out and a recombination center allowing electrons and holes to be quickly recombined.

Thus, the power semiconductor device 400 according to the present exemplary embodiment may reduce OFF loss.

The first cover region 413a may be formed on the resurf region 412.

In the case that the power semiconductor device 400 operates in a blocking mode, a depletion layer formed in a portion where a p-type semiconductor region and an n-type semiconductor region are in contact expands.

Such a depletion layer increasingly expands as a voltage of the blocking mode is increased.

In case of the resurf region 412, since the n-type second semiconductor regions 412a and the p-type third semiconductor regions 412b are in contact, a depletion layer even in the resurf region 412 also expands.

In the case that a voltage is low in an initial stage of the blocking mode, the depletion layer expands in a width direction in the interfaces between the second semiconductor regions 412a and the third semiconductor regions 412b.

In order to enhance a blocking voltage of the power semiconductor device 400, an extra space is required for the depletion layer to expand.

Thus, when a width of each of the second semiconductor regions 412a is W₂, an impurity concentration in each of the second semiconductor regions 412a is C₂, a width of each of the third semiconductor regions 412b is W₃, and an impurity concentration in each of the third semiconductor regions 412b is C₃, W₂, C₂, W₃, and C₃ may be adjusted to satisfy W₂×C₂=W₃×C₃.

In a case in which an amount of impurities of the second semiconductor regions 412a and that of the third semiconductor regions 412b are equal, the second semiconductor regions 412a and the third semiconductor regions 412b may be depleted at the same time.

If the second semiconductor regions 412a and the third semiconductor regions 412b are not depleted at the same time, a depletion layer may expand to upper and lower sides of a first depleted region at a low voltage more than the case in which the second semiconductor regions 112a and the third semiconductor regions 112b are depleted at the same time, reducing a blocking voltage of the power semiconductor device 400.

Thus, in the power semiconductor device 400 according to the present exemplary embodiment, when the width of each of the second semiconductor regions 412a is W₂, the impurity concentration in each of the second semiconductor regions 412a is C₂, the width of each of the third semiconductor regions 412b is W₃, and the impurity concentration in each of the third semiconductor regions 412b is C₃, since W₂×C₂=W₃×C₃ is satisfied, a blocking voltage of the power semiconductor device 400 may be increased.

In the case that the voltage in the blocking mode is increased, the depletion layer depletes the entirety of the resurf region 412 and expands to upper and lower sides.

In the power semiconductor device 400 according to the present exemplary embodiment, an n-type first cover region 413a may be formed on the resurf region 412.

In the case that the power semiconductor device 400 operates in the blocking mode, the first cover region 413a may serve as a field stop, preventing the depletion layer to expand to the drift region 410 and to upper sides of the drift region 410.

Thus, in the case that the power semiconductor device 400 operates in the blocking mode of a high voltage, the first cover region 413a may serve to protect the p-n junction formed as the drift region 410 and the body region 420 are formed to be in contact.

In order to enhance field stop performance of the first cover region 413a, when the width of each of the second semiconductor regions 412a is W₂, an impurity concentration in each of the second semiconductor regions 412a is C₂, the width of each of the third semiconductor regions 412b is W₃, an impurity concentration in each of the third semiconductor regions 412b is C₃, a thickness of the first cover region 413a is T_{c1}, and an impurity concentration in the first cover region 413a is C_{c1}, T_{c1}×C_{c1}≧W₂×C₂=W₃×C₃ may be satisfied.

The first cover region 413a may not be formed to be in direct contact with the body region 420, and an upper surface of the drift region 410 may be formed to be in direct contact with the body region 420.

Namely, conductivity modulation may be induced by forming an n-type impurity region having a low concentration on an upper surface of the drift region 410.

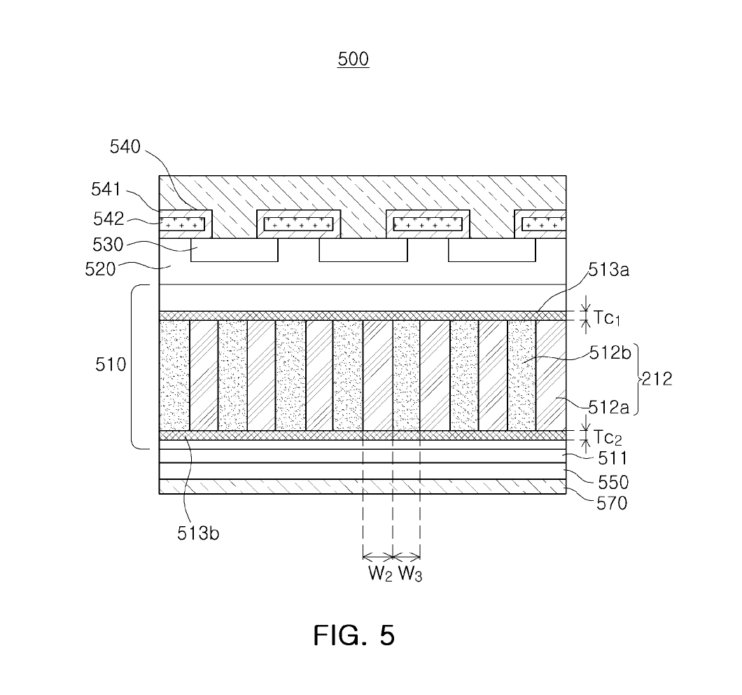

FIG. 5 is a cross-sectional view schematically illustrating a power semiconductor device 500 in which first and second cover regions 513a and 513b are respectively formed above and below a resurf region 512 according to another exemplary embodiment of the present disclosure.

Components not described hereinafter are identical to those of the power semiconductor device 400 illustrated in FIG. 4.

As illustrated in FIG. 5, the first cover region 513a and the second cover region 513b may be formed to be contiguous with upper and lower surfaces of the resurf region 512, respectively.

The second cover region 513b may serve to hinder a depletion layer from expanding downwards in a blocking mode, like the first cover region 513a.

In order to enhance field stop performance of the second cover region 513b, when a width of each of the second semiconductor regions 512a is W₂, an impurity concentration in each of the second semiconductor regions 512a is C₂, a width of each of the third semiconductor regions 512b is W₃, and an impurity concentration in each of the third semiconductor regions 512b is C₃, a thickness of the second cover region 513b is T_{c2}, and an impurity concentration in the second cover region 513b is C_{c2}, T_{c2}×C_{c2}≧W₂×C₂=W₃×C₃ may be satisfied.

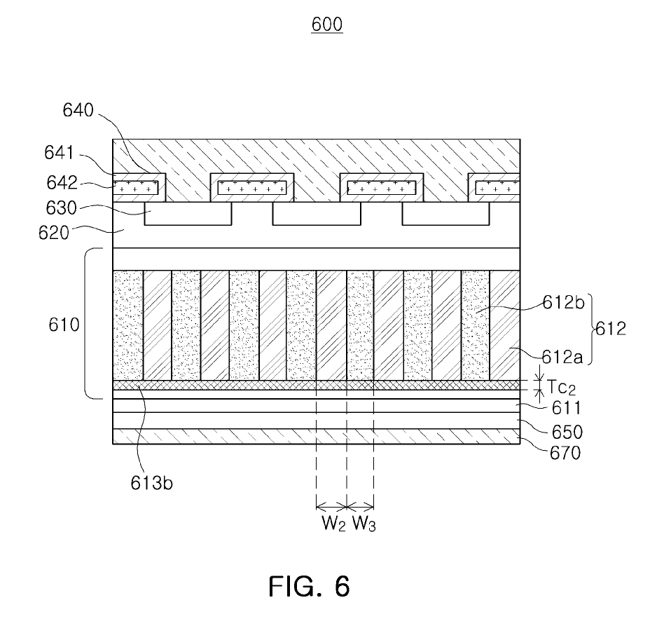

FIG. 6 is a cross-sectional view schematically illustrating a power semiconductor device 600 in which a second cover region 613b is formed below a resurf region 612 according to another exemplary embodiment of the present disclosure.

Components not described hereinafter are identical to those of the power semiconductor device 400 described above with reference to FIG. 4.

As illustrated in FIG. 6, the second cover region 613b may be formed only on a lower surface of the resurf region 612.

In the case in which the resurf region 612 is formed on a lower surface of a drift region 610, since the second cover region 613b is formed only on the lower surface of the resurf region 612, a depletion layer may be hindered from expanding.

As set forth above, according to exemplary embodiments of the present disclosure, in the power semiconductor device, by forming an n-type semiconductor region in the resurf region, a path allowing a current to flow may be provided in the drift region, and thus, ON voltage performance may be enhanced.

Also, in the power semiconductor device, the n-type semiconductor region and the p-type semiconductor region are formed in the resurf region, providing a recombination center allowing electrons and holes remaining in the drift region to be rapidly removed in the case that the power semiconductor device transitions from a conduction state to an OFF state, and thus, OFF loss may be reduced.

Since the power semiconductor device according to the present exemplary embodiment is not reduced in thickness, it may have high short circuit tolerance (capacity), compared to a power semiconductor device in which an ON voltage and OFF loss are reduced by removing a rear surface of a wafer.

Also, by providing a cover region formed in at least one of upper and lower surfaces of the resurf region, in the case that the power semiconductor device operates in the blocking mode, a depletion layer may be hindered or reduced from expanding through the cover region.

Thus, blocking voltage of the power semiconductor device in a high voltage blocking mode may be enhanced.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a first conductivity-type first semiconductor region;
a resurf region disposed in the first semiconductor region and including first conductivity-type second semiconductor regions and second conductivity-type third semiconductor regions alternately disposed in a width direction;
a first conductivity-type first cover region disposed in the first semiconductor region, disposed to be contiguous with an upper surface of the resurf region, and having an impurity concentration higher than that of the first semiconductor region;
a second conductivity-type fourth semiconductor region disposed above the first semiconductor region;
a first conductivity-type fifth semiconductor region disposed on an inner side of an upper portion of the fourth semiconductor region; and
a trench gate disposed to penetrate from the fifth semiconductor region to a portion of an upper portion of the first semiconductor region and including a gate insulating layer disposed on a surface thereof and a conductive material filling the interior of the trench.

2. The power semiconductor device of claim 1, wherein when a width of each of the second semiconductor regions is W₂ an impurity concentration in each of the second semiconductor regions is C₂, a width of each of the third semiconductor regions is W₃, and an impurity concentration in each of the third semiconductor regions is C₃, W₂×C₂=W₃×C₃ is satisfied.

3. The power semiconductor device of claim 1, wherein when a width of each of the second semiconductor regions is W₂, an impurity concentration in each of the second semiconductor regions is C₂, a width of each of the third semiconductor regions is W₃, an impurity concentration in each of the third semiconductor regions is C₃, a thickness of the first cover region is T_{c1}, and an impurity concentration in the first cover region is C_{c1}, T_{c1}×C_{c1}≧W₂×C₂ is satisfied.

4. The power semiconductor device of claim 1, further comprising a second cover region having a first conductivity-type second cover region disposed in the first semiconductor region, disposed to be contiguous with a lower surface of the resurf region, and having an impurity concentration higher than that of the first semiconductor region.

5. The power semiconductor device of claim 4, wherein when a width of each of the second semiconductor regions is W₂, an impurity concentration in each of the second semiconductor regions is C₂, a width of each of the third semiconductor regions is W₃, and an impurity concentration in each of the third semiconductor regions is C₂, a thickness of the second cover region is T_{c2}, and an impurity concentration in the second cover region is C_{c2}, T_{c2}×C_{c2}≧W₂×C₂ is satisfied.

6. A power semiconductor device comprising:
a first conductivity-type first semiconductor region;
a first conductivity-type second cover region disposed in the first semiconductor region and having an impurity concentration higher than that of the first semiconductor region;
a resurf region disposed in the first semiconductor region, disposed to be contiguous with an upper surface of the second cover region, and including first conductivity-type second semiconductor regions and second conductivity-type third semiconductor regions alternately disposed in a width direction;
a second conductivity-type fourth semiconductor region disposed above the first semiconductor region;
a first conductivity-type fifth semiconductor region disposed on an inner side of an upper portion of the fourth semiconductor region; and
a trench gate disposed to penetrate from the fifth semiconductor region to a portion of an upper portion of the first semiconductor region and including a gate insulating layer disposed on a surface thereof and a conductive material filling the interior of the trench.

7. A power semiconductor device comprising:
a first conductivity-type first semiconductor region;
a resurf region disposed in the first semiconductor region and including first conductivity-type second semiconductor regions and second conductivity-type third semiconductor regions alternately disposed in a width direction;
a first conductivity-type first cover region disposed in the first semiconductor region, disposed to be contiguous with an upper surface of the resurf region, and having an impurity concentration higher than that of the first semiconductor region;
a second conductivity-type fourth semiconductor region disposed above the first semiconductor region;
a first conductivity-type fifth semiconductor region disposed on an inner side of an upper portion of the fourth semiconductor region; and
a gate disposed above the fourth semiconductor region.

8. The power semiconductor device of claim 7, wherein when a width of each of the second semiconductor regions is W₂, an impurity concentration in each of the second semiconductor regions is C₂, a width of each of the third semiconductor regions is W₃, and an impurity concentration in each of the third semiconductor regions is C₃, W₂×C₂=W₃×C₃ is satisfied.

9. The power semiconductor device of claim 7, wherein when a width of each of the second semiconductor regions is W₂, an impurity concentration in each of the second semiconductor regions is C₂, a width of each of the third semiconductor regions is W₃, an impurity concentration in each of the third semiconductor regions is C₃, a thickness of the first cover region is T_{c1}, and an impurity concentration in the first cover region is C_{c1}, T_{c1}×C_{c1}≧W₂×C₂ is satisfied.

10. The power semiconductor device of claim 7, further comprising a second cover region having a first conductivity-type second cover region disposed in the first semiconductor region, disposed to be contiguous with a lower surface of the resurf region, and having an impurity concentration higher than that of the first semiconductor region.

11. The power semiconductor device of claim 10,
wherein when a width of each of the second semiconductor regions is W₂, an impurity concentration in each of the second semiconductor regions is C₂, a width of each of the third semiconductor regions is W₃, and an impurity concentration in each of the third semiconductor regions is C₃, a thickness of the second cover region is T_{c2}, and an impurity concentration in the second cover region is C_{c2}, T_{c2}×C_{c2}≧W₂×C₂ is satisfied.

12. A power semiconductor device comprising:
a first conductivity-type first semiconductor region;
a first conductivity-type second cover region disposed in the first semiconductor region and having an impurity concentration higher than that of the first semiconductor region;
a resurf region disposed in the first semiconductor region, disposed to be contiguous with an upper surface of the second cover region, and including first conductivity-type second semiconductor regions and second conductivity-type third semiconductor regions alternately disposed in a width direction;
a second conductivity-type fourth semiconductor region disposed above the first semiconductor region;
a first conductivity-type fifth semiconductor region disposed on an inner side of an upper portion of the fourth semiconductor region; and
a gate disposed above the fourth semiconductor region.
